(19) United States
(12) Patent Application Publication
(10) Pub. No.: US 2026/0280575 A1
(43) Pub. Date: Sep. 17, 2026

(54) DIGITAL TO ANALOG CONVERTER CORRECTION BASED ON READING A CHANNEL OF THE DIGITAL TO ANALOG CONVERTER

(71) Applicant: Microchip Technology Inc., Chandler, AZ (US)

(72) Inventors: Naveen Raj, Chandler, AZ (US); Vincent Quiquempoix, Divonne-Les-Bains (FR); Aditya Deshpande, Chandler, AZ (US); Pat Richards, Peoria, AZ (US)

(73) Assignee: Microchip Technology Inc., Chandler, AZ (US)

(21) Appl. No.: 19/199,549

(22) Filed: May 6, 2025

Related U.S. Application Data
(60) Provisional application No. 63/760,743, filed on Feb. 20, 2025.

(51) Int. Cl. H03M 1/06; H03M 1/00; H03M 1/12

(52) U.S. Cl. CPC H03M 1/0607; H03M 1/007; H03M 1/1205

(57) ABSTRACT

A system and method for a digital-to-analog converter that performs error correction in real-time during operation are disclosed. The method may include receiving an input from an analog-to-digital converter (ADC) communicatively coupled to a digital-to-analog converter (DAC) having a plurality of channels. The input may be indicative of an output of a channel of the plurality of channels. The method may also include calculating a compensation input to correct an error of the channel. The method may additionally include outputting the compensation input to an input to the DAC. The method may further include correcting the output of the plurality of channels based on the compensation input.

### PRIORITY

This application claims priority to U.S. Provisional Patent Application No. 63/760,743 filed Feb. 20, 2025, the contents of which are hereby incorporated in their entirety.

### TECHNICAL FIELD

The present disclosure relates to digital-to-analog converters, and, in particular, to a digital-to-analog converter that performs error correction in real-time during operation.

### BACKGROUND

A digital-to-analog converter (DAC) is a device that converts a digital signal into an analog signal. DACs are used in a wide variety of applications, including, but not limited to, audio, video, communications, and industrial control. The resolution of a DAC is a measure of how accurately it can convert a digital signal into an analog signal. The higher the resolution, the more accurate the conversion will be. The linearity of a DAC is a measure of how closely the output of the DAC matches the input. A perfectly linear DAC would produce an output that is exactly proportional to the input.

Higher resolution DACs generally have higher costs. The increased complexity, precision, and testing performed for higher resolution DACs contribute to higher production costs. Accurately measuring and testing the performance of higher resolution DACs uses specialized equipment and techniques. This can add to the development time and cost, and manufacturers may invest in new testing infrastructure to test higher resolution DACs. It can also make higher resolution DACs less accessible to consumers and limit their adoption in price-sensitive applications.

### SUMMARY OF THE INVENTION

Aspects provide systems and methods for a digital-to-analog converter that performs error correction in real-time during operation. Examples of the present disclosure may include an apparatus. The apparatus may include a first interface communicatively coupled to a digital-to-analog converter (DAC) having a plurality of channels. The apparatus may also include a second interface communicatively coupled to an analog-to-digital converter (ADC) communicatively coupled to the DAC. The ADC may be configured to read a channel of the plurality of channels. The apparatus may further include a control circuit communicatively coupled to the first interface and the second interface. The control circuit may be configured to receive an input from the ADC indicative of an output of the channel. The control circuit may also be configured to calculate a compensation input to correct an error of the channel. The control circuit may additionally be configured to output the compensation input to an input to the DAC. The control circuit may further be configured to correct an output of the plurality of channels based on the compensation input.

In combination with any of the above examples, the ADC may include a multiplexer communicatively coupled to the plurality of channels. The ADC may be configured to read the plurality of channels in a sequenced manner. The control circuit may be configured to correct an output of each of the plurality of channels.

In combination with any of the above examples, the apparatus may include a second DAC having a second plurality of channels. The ADC may be configured to read a second channel of the second plurality of channels. The control circuit may be configured to receive a second input from the ADC indicative of an output of the second channel. The control circuit may also be configured to calculate a second compensation input to correct a second error of the second channel. The control circuit may additionally be configured to output the second compensation input to a second input to the second DAC. The control circuit may further be configured to correct the output of the second plurality of channels based on the second compensation input.

In combination with any of the above examples, the control circuit may be configured to calculate the compensation input by comparing the input from the ADC to an ideal output of the channel.

In combination with any of the above examples, the compensation input may be calculated in real-time while the DAC is operational.

In combination with any of the above examples, the error may be at least one of an offset error or a gain error.

In combination with any of the above examples, a resolution of the ADC may be greater than a resolution of the DAC.

Alone or in combination with any of the above examples, examples of the present disclosure may include a system. The system may include a digital-to-analog converter (DAC) having a plurality of channels. The system may also include an analog-to-digital converter (ADC) communicatively coupled to the DAC. The ADC may be configured to read a channel of the plurality of channels. The system may further include a control circuit communicatively coupled to the DAC and the ADC. The control circuit may be configured to receive an input from the ADC indicative of an output of the channel. The control circuit may also be configured to calculate a compensation input to correct an error of the channel. The control circuit may additionally be configured to output the compensation input to an input to the DAC. The control circuit may further be configured to correct the output of the plurality of channels based on the compensation input.

In combination with any of the above examples, the ADC may include a multiplexer communicatively coupled to the plurality of channels. The ADC may be configured to read the plurality of channels in a sequenced manner.

In combination with any of the above examples, the system may include a second DAC having a second plurality of channels. The ADC may be configured to read a second channel of the second plurality of channels. The control circuit may be configured to receive a second input from the ADC indicative of an output of the second channel. The control circuit may also be configured to calculate a second compensation input to correct a second error of the second channel. The control circuit may additionally be configured to output the second compensation input to a second input to the second DAC. The control circuit may further be configured to correct the output of the second plurality of channels based on the second compensation input.

In combination with any of the above examples, the control circuit may be configured to calculate the compensation input by comparing the input from the ADC to an ideal output of the channel.

In combination with any of the above examples, the compensation input may be calculated in real-time while the DAC is operational.

In combination with any of the above examples, the error may be at least one of an offset error or a gain error.

In combination with any of the above examples, a resolution of the ADC may be greater than a resolution of the DAC.

Alone or in combination with any of the above examples, examples of the present disclosure may include a method. The method may include receiving an input from an analog-to-digital converter (ADC) communicatively coupled to a digital-to-analog converter (DAC) having a plurality of channels. The input may be indicative of an output of a channel of the plurality of channels. The method may also include calculating a compensation input to correct an error of the channel. The method may additionally include outputting the compensation input to an input to the DAC. The method may further include correcting the output of the plurality of channels based on the compensation input.

In combination with any of the above examples, the method may include receiving a plurality of inputs from the ADC indicative of a plurality of outputs of the plurality of channels. A given output of the plurality of outputs may correspond to a given channel of the plurality of channels. For each of the plurality of outputs, the method may include calculating a given compensation input to correct an error of the given channel, outputting the given compensation input to the DAC, and correcting the given output based on the compensation input.

In combination with any of the above examples, the method may include receiving a second input from the ADC indicative of an output of the second channel. The method may also include calculating a second compensation input to correct a second error of the second channel. The method may additionally include outputting the second compensation input to a second input to the second DAC. The method may further include correcting the output of the second plurality of channels based on the second compensation input.

In combination with any of the above examples, the method may include calculating the compensation input by comparing the input from the ADC to an ideal output of the channel.

In combination with any of the above examples, calculating the compensation input may be performed in real-time while the DAC is operational.

In combination with any of the above examples, the error may be at least one of an offset error or a gain error.

### BRIEF DESCRIPTION OF THE DRAWINGS

The figures illustrate examples of systems and methods for a digital-to-analog converter (DAC) that performs error correction in real-time during operation.

FIG. 1 illustrates a block diagram of a system including a digital-to-analog converter (DAC) to perform error correction in real-time during operation, according to examples of the present disclosure;

FIG. 2 illustrates a graph of the error across the codes of the channels of an eight channel DAC, according to examples of the present disclosure;

FIG. 3 illustrates a method for performing error correction in real time for a digital to analog converter, according to examples of the present disclosure; and

FIG. 4 illustrates a more detailed version of the method shown in FIG. 3 for performing error correction in real time for a digital to analog converter, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a digital-to-analog converter (DAC) that performs error correction in real-time during operation is provided. The DAC may be self-learning to achieve a stable output of the DAC across operating conditions. Because the DAC is self-learning and calibrated at run time, the time to test the DAC during manufacturing. The DAC may be used in applications to achieve accuracy across all conditions and in applications where the environment may change during the product life cycle.

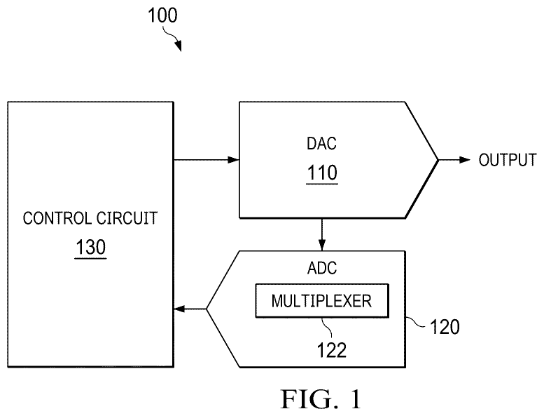

FIG. 1 illustrates a block diagram of a system including a digital-to-analog converter (DAC) to perform error correction in real-time during operation, according to examples of the present disclosure. System 100 may include DAC 110, analog-to-digital converter (ADC) 120, and control circuit 130.

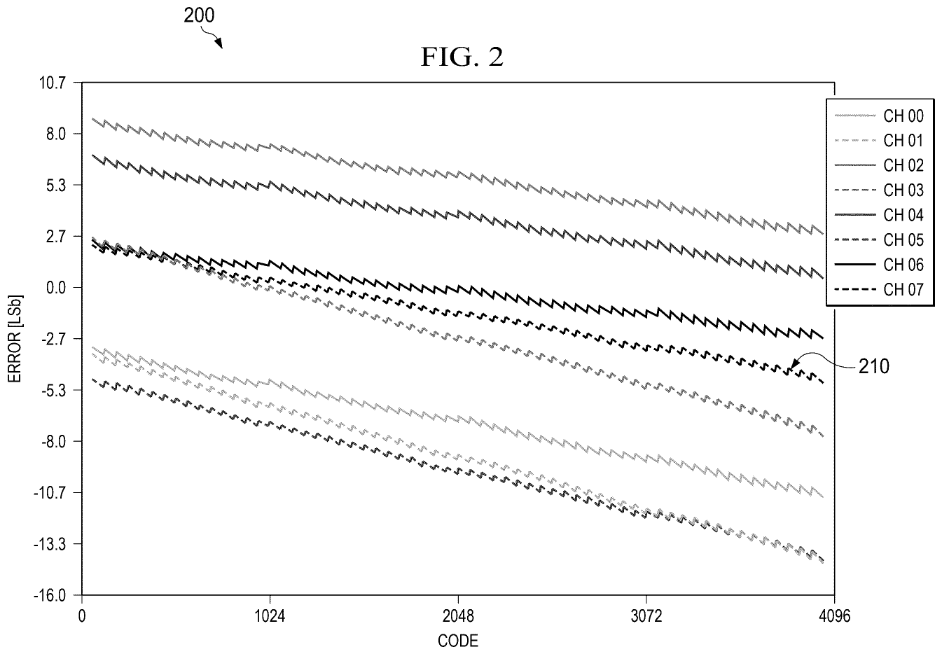

DAC 110 may be any suitable digital-to-analog converter having multiple channels. One or more channels of DAC 110 may be used for error correction. For example, in examples where DAC 110 has eight channels, one channel (e.g., channel 7) may be referred to as a “dummy channel” and used as an error correction channel. The error correction channel may be selected based on the error of each channel of DAC 110. For example, FIG. 2 illustrates a graph 200 of the error across the codes of the channels of an eight channel DAC, according to examples of the present disclosure. In the example shown in FIG. 2, line 210 corresponds to a channel of the DAC having an error approximately in the middle of the errors of the other channels. Therefore, the channel corresponding to line 210 (e.g., channel 7 in graph 200) may be selected as the error correction channel. In other examples, the error correction channel may be selected based on the performance metric (e.g., offset error, gain error, integral nonlinearity, differential nonlinearity) which the user has selected to correct. For example, where the user selects to correct the offset error, the error correction channel may be selected based on a channel near the average of the offset error.

ADC 120 may be communicatively coupled to the error correction channel of DAC 110. ADC 120 may be any suitable analog-to-digital converter. ADC 120 may have a resolution higher than the resolution of DAC 110 (e.g., the resolution of ADC 120 may be at least 2-bits higher than the resolution of DAC 110). For example, DAC 110 may be a 12-bit DAC and ADC 120 may be a 24-bit ADC. The ratio of the resolution of ADC 120 to the resolution to DAC 110 may depend on the application in which DAC 110 is used, the linearity of DAC 110, or any combination thereof. ADC 120 may convert the analog value from the error correction channel to a digital code and output the digital code. DAC 110 and ADC 120 may be electrically coupled to the same reference voltage.

The digital code output of ADC 120 may be communicatively coupled to control circuit 130. Control circuit 130 may calculate the error correction to apply to DAC 110 using the digital code output by ADC 120. In some examples, control circuit 130 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 130 may be implemented by instructions for execution by a processor through, for example, a function, application programming interface (API) call, script, program, compiled code, interpreted code, binary, executable, executable file, firmware, object file, container, assembly code, or object. For example, control circuit 130 may be implemented by instructions stored in a non-transitory medium such as a memory that, when loaded and executed by a processor such as a central processing unit (CPU) (or any other suitable process), cause the functionality of control circuit 130 described herein. Control circuit 130 may be implemented on the same chip as DAC 110 and ADC 120 or implemented on a separate chip.

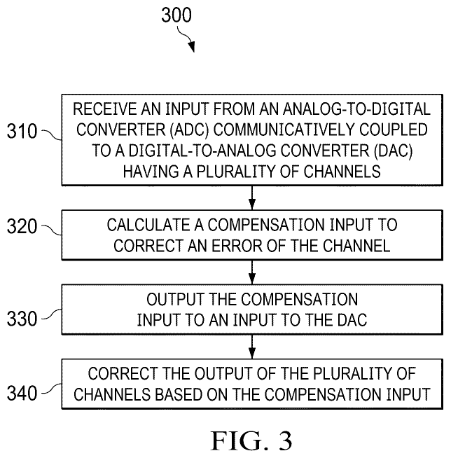

Control circuit 130 may receive the digital code output by ADC 120 (representing the output of the error correction channel) and determine the error correction to apply to DAC 110. The error correction may be determined by using the digital code representing the output of the error correction channel and identifying the error correction using a lookup table, an equation, or a comparison to the ideal data. The error correction may be output to DAC 110 to be added to the input of DAC 110. The process of determining the error correction is described in more detail with respect to FIG. 3.

In some examples, ADC 120 may be coupled to more than one channel of DAC 110. Specifically, ADC 120 may include multiplexer 122 and be communicatively coupled to multiple channels of DAC 110. In this example, multiplexer 122 may select between the multiple channels of DAC 110 and receive the output of the selected channel of DAC 110. The selected channel of DAC 110 may be the error correction channel. ADC 120 may convert the analog voltage output of the selected channel to a digital code and output the digital code to control circuit 130. Control circuit 130 may determine the error correction to apply to the selected channel of DAC 110. In this example, control circuit 130 may perform error correction on a channel-by-channel basis rather than apply the same error correction to other channels of DAC 110 based on one error correction channel. Multiplexer 122 may read the channels of DAC 110 in a sequenced manner such that the outputs of the channels of DAC 110 are received by ADC 120 and control circuit 130 determines an error correction for the channels in order.

By implementing system 100, the time to test DAC 110 may be reduced, even as the resolution of DAC 110 increases because control circuit 130 determines the error correction while DAC 110 is in use instead of the error correction being determined during manufacturing and testing. Therefore, a higher number of channels of DAC 110 may be achieved while not increasing the cost of DAC 110 because the manufacturing and testing costs are not increased. Further, the cost of implementing system 100, including the feedback loop from DAC 110 to ADC 120 to control circuit 130, may be reduced as the process technology shrinks. For example, the die size of ADC 120 in a resistor ladder DAC 110 may be smaller compared to the die size of DAC 110.

Because system 100 includes a feedback loop, DAC 110 may be used in functional safety applications (e.g., automotive, factory automation) where feedback may be used for failure detection. The performance of DAC 110 may change based on the temperature of the operating environment of DAC 110. Some conventional systems may include a temperature sensor so that the error correction value may correspond to the temperature of the operating environment. However, using system 100, the use of a temperature sensor may be eliminated because the error correction value is determined in real-time based on the output of an error correction channel of DAC 110.

FIG. 3 illustrates a method for performing error correction in real time for a digital to analog converter, according to examples of the present disclosure. Method 300 may be implemented using a system including a DAC, an ADC, and a control circuit, or any other system operable to implement method 300. For example, method 300 may be implemented by system 100 shown in FIG. 1. Although examples have been described above, other variations and examples may be made from this disclosure without departing from the spirit and scope of these disclosed examples.

Method 300 may begin at block 310 where a control circuit, such as control circuit 130 shown in FIG. 1, may receive an input from an ADC, such as ADC 120 shown in FIG. 1, that is communicatively coupled to a DAC, such as DAC 110 shown in FIG. 1. The DAC may have a plurality of channels and one channel of the DAC may be used as the error correction channel at a given time. For example, one channel of the DAC may be reserved as the error correction channel. As another example, as described below, the ADC may include a multiplexer and may cycle through the channels of the DAC in a sequenced manner such that many channels of the DAC serve as error correction channels at different times.

The input from the ADC may be indicative of an output of the error correction channel of the DAC. The DAC may receive an input code and output an analog voltage. The ADC read the analog voltage from the error correction channel. For example, the ADC may periodically read an error correction channel of the DAC. In some examples, the ADC may include a multiplexor and may read multiple channels of the DAC in a sequenced manner. The ADC may convert the analog voltage to a digital code. The digital code may be output to the control circuit. The ADC may run continuously while the DAC is in operation.

At block 320, the control circuit may calculate a compensation input to correct an error of the channel. The compensation input may be calculated in real-time while the DAC is operational. The control circuit may run the input codes for the DAC and compare the output of the DAC with the expected output of the DAC. The comparison may use a lookup table or an equation. For example, when the comparison uses a lookup table, the control circuit may identify the error at a given DAC input code. The lookup table may be a table of DAC input codes and corresponding errors. The lookup table may be created in real time. For example, a plurality of input codes may periodically be input to the DAC. The ADC may read the error correction channel at the input codes. The control circuit may receive the readings from the ADC, compare the reading with the given input code, calculate an errors for the input codes, and store the errors in an internal RAM as the look up table. The look up table may be updated based on changing the environment in which the DAC operates (e.g., updated when the temperature of the environment changes). The control circuit may then use the lookup table to calculate compensation inputs in future calculations. The lookup table may be created or updated when the DAC is not in use.

As another example, when the comparison uses an equation, the control circuit may determine an error by inputting the output of the ADC into an equation that identifies the error at a given ADC output. The comparison may also compare the output of the DAC with the ideal output of the DAC. The ideal output may be mathematically calculated. The ideal output may be calculated using the following formula:

$$DAC output = \frac{Digital Input Code * {V}_{R E F}}{{2}^{n}}$$

where V_{REF} is the reference voltage and n is the number of bits of the DAC (e.g., 8-bits, 12-bits, 16-bits). For example, where the DAC is a 12-bit DAC and the DAC input code is 100, the ideal output is 0.061 volts. If the output of the error correction channel is high, such as 0.062 volts, the error correction may be calculated to reduce the output of the DAC by one input code such that the output equals 0.061 volts. If, on the other hand, the output of the DAC is low, such as 0.060 volts, the error correction may be calculated to increase the output of the DAC by one input code such that the output equals 0.061 volts. And, if the output of the DAC equals the ideal output, no error correction is needed.

At block 330, the control circuit may output the compensation input to an input to the DAC. The control circuit may prepare a compensation input for each input code of the DAC. The control circuit may prepare the compensation input at run time as part of a feedback loop while the DAC operates. In examples where the DAC is to have faster operations, the compensation input may be saved to memory, such as random access memory (RAM). In examples where speed is not a concern, a given channel (as opposed to using an error correction channel) may be read to prepare the compensation input.

At block 340, the control circuit may correct the output of the plurality of channels of the DAC based on the compensation input. For example, the control circuit may add the compensation input to the input to the DAC such that the error in the DAC is mitigated. The compensation input may be applied to the plurality of channels of the DAC based on the compensation input calculated based on the error correction channel. Method 300 may be performed in real-time while the DAC is operational.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

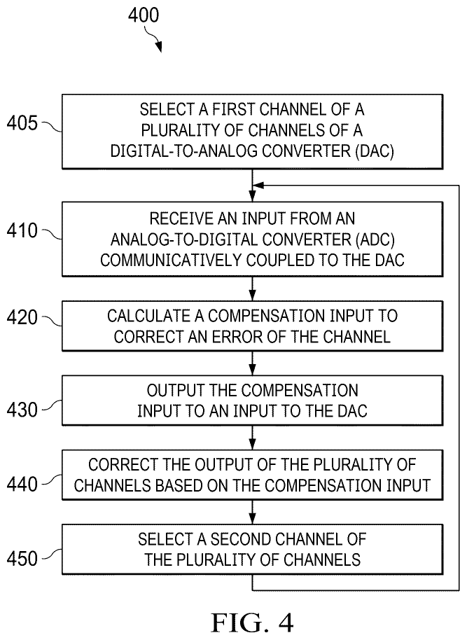

FIG. 4 illustrates a more detailed version of the method shown in FIG. 3 for performing error correction in real time for a digital to analog converter, according to examples of the present disclosure. Method 400 may be implemented using a system including a DAC, an ADC, and a control circuit, or any other system operable to implement method 400. For example, method 400 may be implemented by system 100 shown in FIG. 1. Although examples have been described above, other variations and examples may be made from this disclosure without departing from the spirit and scope of these disclosed examples.

Method 400 may begin at block 405 where a first channel of a first plurality of channels of a DAC, such as DAC 110 shown in FIG. 1, may be selected. The selection may be performed by a multiplexer of an ADC, such as ADC 120 shown in FIG. 1. The DAC may have a plurality of channels and one channel of the DAC may be used as the error correction channel at a given time. For example, one channel of the DAC may be reserved as the error correction channel. As another example, as described below, the ADC may include a multiplexer and may cycle through the channels of the DAC in a sequenced manner such that many channels of the DAC serve as error correction channels at different times.

At block 410, the control circuit, such as control circuit 130 shown in FIG. 1, may receive an input from the ADC that is communicatively coupled to the DAC. The input from the ADC may be indicative of an output of the selected error correction channel of the DAC (selected at block 405). The DAC may receive an input code and output an analog voltage. The ADC read the analog voltage from the error correction channel. For example, the ADC may periodically read an error correction channel of the DAC. In some examples, the ADC may include a multiplexor and may read multiple channels of the DAC in a sequenced manner. The ADC may convert the analog voltage to a digital code. The digital code may be output to the control circuit. The ADC may run continuously while the DAC is in operation.

At block 420, the control circuit may calculate a compensation input to correct an error of the channel. The control circuit may run the input codes for the DAC and compare the output of the DAC with the expected output of the DAC. The comparison may use a lookup table or an equation. For example, when the comparison uses a lookup table, the control circuit may identify the error at a given DAC input code. The lookup table may be created in real time. For example, a plurality of input codes may periodically be input to the DAC. The ADC may read the error correction channel at the input codes. The control circuit may receive the readings from the ADC, compare the reading with the given input code, calculate an errors for the input codes, and store the errors in an internal RAM as the look up table. The look up table may be updated based on changing the environment in which the DAC operates (e.g., updated when the temperature of the environment changes). The control circuit may then use the lookup table to calculate compensation inputs in future calculations. The lookup table may be created or updated when the DAC is not in use.

As another example, when the comparison uses an equation, the control circuit may determine an error by inputting the output of the ADC into an equation that identifies the error at a given ADC output. The comparison may also compare the output of the DAC with the ideal output of the DAC. The ideal output may be mathematically calculated. The ideal output may be calculated using the following formula:

$$DAC output = \frac{Digital Input Code * {V}_{R E F}}{{2}^{n}}$$

where V_{REF} is the reference voltage and n is the number of bits of the DAC (e.g., 8-bits, 12-bits, 16-bits). For example, where the DAC is a 12-bit DAC and the DAC input code is 100, the ideal output is 0.061 volts. If the output of the error correction channel is high, such as 0.062 volts, the error correction may be calculated to reduce the output of the DAC by one input code such that the output equals 0.061 volts. If, on the other hand, the output of the DAC is low, such as 0.060 volts, the error correction may be calculated to increase the output of the DAC by one input code such that the output equals 0.061 volts. And, if the output of the DAC equals the ideal output, no error correction is needed.

At block 430, the control circuit may output the compensation input to an input to the DAC. The control circuit may prepare a compensation input for each input code of the DAC. The control circuit may prepare the compensation input at run time as part of a feedback loop while the DAC operates. In examples where the DAC is to have faster operations, the compensation input may be saved to memory, such as random access memory (RAM).

At block 440, the control circuit may correct the output of the plurality of channels of the DAC based on the compensation input. For example, the control circuit may add the compensation input to the input to the DAC such that the error in the DAC is mitigated. The compensation input may be applied to the plurality of channels of the DAC based on the compensation input calculated based on the error correction channel.

At block 450, the multiplexer may select a second channel of the plurality of channels of the DAC. Method 400 may return to block 410 where the control circuit may calculate a compensation input based on the second channel. Method 400 may continue to cycle through the channels of the DAC to correct the channels in a sequenced manner. For example, method 400 may cycle through the channels of the DAC in a round-robin manner. Method 400 may be performed in real-time while the DAC is operational.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

While the examples described above describe error correction in a DAC, the disclosed method may be used for error correction in other electronic components having multiple channels.

Although examples have been described above, other variations and examples may be made from this disclosure without departing from the spirit and scope of these disclosed examples.

1. An apparatus, comprising:
a first interface communicatively coupled to a digital-to-analog converter (DAC) having a plurality of channels;
a second interface communicatively coupled to an analog-to-digital converter (ADC) communicatively coupled to the DAC, wherein the ADC is configured to read a channel of the plurality of channels; and
a control circuit communicatively coupled to the first interface and the second interface, the control circuit configured to:
receive an input from the ADC indicative of an output of the channel;
calculate a compensation input to correct an error of the channel;
output the compensation input to an input to the DAC; and
correct an output of the plurality of channels based on the compensation input.

2. The apparatus of claim 1, wherein:
the ADC includes a multiplexer communicatively coupled to the plurality of channels;
the ADC is configured to read the plurality of channels in a sequenced manner; and
the control circuit is configured to correct an output of each of the plurality of channels.

3. The apparatus of claim 1, comprising:
a second DAC having a second plurality of channels;
wherein:
the ADC is configured to read a second channel of the second plurality of channels; and
the control circuit is configured to:
receive a second input from the ADC indicative of an output of the second channel;
calculate a second compensation input to correct a second error of the second channel;
output the second compensation input to a second input to the second DAC; and
correct the output of the second plurality of channels based on the second compensation input.

4. The apparatus of claim 1, wherein the control circuit is configured to calculate the compensation input by comparing the input from the ADC to an ideal output of the channel.

5. The apparatus of claim 1, wherein the compensation input is calculated in real-time while the DAC is operational.

6. The apparatus of claim 1, wherein the error is at least one of an offset error or a gain error.

7. The apparatus of claim 1, wherein a resolution of the ADC is greater than a resolution of the DAC.

8. A system, comprising:
a digital-to-analog converter (DAC) having a plurality of channels;
an analog-to-digital converter (ADC) communicatively coupled to the DAC, wherein the ADC is configured to read a channel of the plurality of channels; and
a control circuit communicatively coupled to the DAC and the ADC, the control circuit configured to:
receive an input from the ADC indicative of an output of the channel;
calculate a compensation input to correct an error of the channel;
output the compensation input to an input to the DAC; and
correct the output of the plurality of channels based on the compensation input.

9. The system of claim 8, wherein:
the ADC includes a multiplexer communicatively coupled to the plurality of channels; and
the ADC is configured to read the plurality of channels in a sequenced manner.

10. The system of claim 8, comprising:
a second DAC having a second plurality of channels;
wherein:
the ADC is configured to read a second channel of the second plurality of channels; and
the control circuit is configured to:
receive a second input from the ADC indicative of an output of the second channel;
calculate a second compensation input to correct a second error of the second channel;
output the second compensation input to a second input to the second DAC; and
correct the output of the second plurality of channels based on the second compensation input.

11. The system of claim 8, wherein the control circuit is configured to calculate the compensation input by comparing the input from the ADC to an ideal output of the channel.

12. The system of claim 8, wherein the compensation input is calculated in real-time while the DAC is operational.

13. The system of claim 8, wherein the error is at least one of an offset error or a gain error.

14. The system of claim 8, wherein a resolution of the ADC is greater than a resolution of the DAC.

15. A method, comprising:
receiving an input from an analog-to-digital converter (ADC) communicatively coupled to a digital-to-analog converter (DAC) having a plurality of channels, wherein the input is indicative of an output of a channel of the plurality of channels;
calculating a compensation input to correct an error of the channel;
outputting the compensation input to an input to the DAC; and
correcting the output of the plurality of channels based on the compensation input.

16. The method of claim 15, comprising:
receiving a plurality of inputs from the ADC indicative of a plurality of outputs of the plurality of channels, a given output of the plurality of outputs corresponding to a given channel of the plurality of channels; and
for each of the plurality of outputs:
calculating a given compensation input to correct an error of the given channel;
outputting the given compensation input to the DAC; and
correcting the given output based on the compensation input.

17. The method of claim 15, comprising:
receiving a second input from the ADC indicative of an output of the second channel;
calculating a second compensation input to correct a second error of the second channel;
outputting the second compensation input to a second input to the second DAC; and
correcting the output of the second plurality of channels based on the second compensation input.

18. The method of claim 15, comprising calculating the compensation input by comparing the input from the ADC to an ideal output of the channel.

19. The method of claim 15, wherein calculating the compensation input is performed in real-time while the DAC is operational.

20. The method of claim 15, wherein the error is at least one of an offset error or a gain error.
